(19) United States
(12) Patent Application Publication
(10) Pub. No.: US 2008/0105899 A1
(43) Pub. Date: May 8, 2008

(54) SEMICONDUCTOR DEVICE WITH EPITAXIALLY GROWN LAYER AND FABRICATION METHOD

(75) Inventors: Young-pil KIM, Suwon-si (KR); Jin-bum KIM, Gwanak-gu (KR); Jun-ho LEE, Songpa-gu (KR); Jung-yun WON, Hwaseong-si (KR); In-sun JUNG, Suwon-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Gyeonggi-do (KR)

(21) Appl. No.: 11/858,288

(22) Filed: Sep. 20, 2007

(30) Foreign Application Priority Data
Nov. 3, 2006 (KR) 1020060108401

(51) Int. Cl. H01L 29/778; H01L 21/336

(52) U.S. Cl. 257/192; 438/300; 257/E29.246; 257/E21.409

(57) ABSTRACT

A fabrication method and a related semiconductor device are disclosed. The method includes; forming a gate structure on a semiconductor substrate, the gate structure comprising a stacked combination a gate dielectric pattern, a gate, a capping layer pattern and an epitaxial blocking layer pattern, forming sidewall spacers on the gate structure covering at least sidewall portions of the gate dielectric pattern, the gate, and the capping layer pattern, wherein the epitaxial blocking layer pattern is exposed on a top surface of the gate structure, forming an elevated epitaxial layer on the semiconductor substrate outside the gate structure using a selective epitaxial growth process, and forming elevated source/drain regions by applying an ion implantation process to the semiconductor substrate following formation of the elevated epitaxial layer, wherein the epitaxial blocking layer is a nitrogen enhanced layer relative to the capping layer pattern.

### CROSS REFERENCE TO RELATED APPLICATION

This application claims priority from Korean Patent Application No. 10-2006-0108401 filed on Nov. 3, 2006, the subject mater of which is hereby incorporated by reference.

### BACKGROUND OF THE INVENTION

1. Field of the Invention

The present invention relates to a semiconductor device and a method of fabrication. More particularly, the present invention relates to a semiconductor device having an epitaxially grown silicon layer, and a method of fabrication

2. Description of the Related Art

In attempting to further increase the integration density of contemporary semiconductor devices, various techniques have been proposed to elevate source/drain regions during fabrication of the devices. Some of these techniques use a selective epitaxial growth process to form the elevated source/drain regions.

This process selectively grows silicon in defined portions of an active region of a semiconductor substrate by providing certain silicon source gases, such as dichlorosilane (DCS; SiH2Cl2) and SiH4. Using this process, exposed portions of the semiconductor substrate have silicon grown thereon. These portions subsequently serve as source/drain regions. Other unexposed portions of the semiconductor substrate, such as portions covered by an oxide layer or nitride layer do not have silicon grown thereon. In order to prevent silicon from growing on the oxide or nitride layers, HCl and/or Cl2 gas is supplied with the silicon source gas, because it has been determined that a gas containing Cl atoms improves the selectivity of selective growth process between exposed portions of a semiconductor substrate containing silicon and other material layers.

However, the additionally supplied Cl gas may also etch the exposed portions of the semiconductor substrate in undesirable ways. This etching effect actually works against the enhanced selectivity intended by the addition of a Cl gas into the selective epitaxial growth process. As a greater volume of the Cl gas is introduced into the selective epitaxial growth process to increase selectivity, the etch damage due to the Cl atom also increases, thereby working against the desired selectivity. Thus, a method having improved overall selectivity is needed.

### SUMMARY OF THE INVENTION

Embodiments of the invention provide a method of fabricating a semiconductor device having improved reliability and epitaxial growth selectivity, as well as the resulting semiconductor devices.

In one embodiment, the invention provides a method of fabricating a semiconductor device, comprising; sequentially forming a dielectric layer, a conductive layer, a capping layer, an epitaxial blocking layer, and a sacrificial hard mask layer on a semiconductor substrate, forming a photoresist pattern on the sacrificial hard mask layer, using the photoresist pattern as a mask, patterning the sacrificial hard mask layer to form a sacrificial hard mask pattern, patterning the epitaxial blocking layer to form an epitaxial blocking layer pattern, and patterning the capping layer to form a capping layer pattern, patterning the conductive layer to form a gate and patterning the dielectric layer to form a gate dielectric pattern, wherein the epitaxial blocking layer pattern, capping layer pattern, the gate, and gate oxide pattern form a gate structure, conformally forming a spacer insulating layer on the semiconductor substrate including the gate structure, forming spacers by anisotropically etching the spacer insulating layer to expose the epitaxial blocking layer pattern, forming an elevated epitaxial layer on the semiconductor substrate outside the gate structure using a selective epitaxial growth process, and forming elevated source/drain regions by applying an ion implantation process to the semiconductor substrate following formation of the elevated epitaxial layer.

In another embodiment, the invention provides a method of fabricating a semiconductor device, comprising; forming a gate structure on a semiconductor substrate, the gate structure comprising a stacked combination a gate dielectric pattern, a gate, a capping layer pattern and an epitaxial blocking layer pattern, forming sidewall spacers on the gate structure covering at least sidewall portions of the gate dielectric pattern, the gate, and the capping layer pattern, wherein the epitaxial blocking layer pattern is exposed on a top surface of the gate structure, forming an elevated epitaxial layer on the semiconductor substrate outside the gate structure using a selective epitaxial growth process, and forming elevated source/drain regions by applying an ion implantation process to the semiconductor substrate following formation of the elevated epitaxial layer, wherein the epitaxial blocking layer is a nitrogen enhanced layer relative to the capping layer pattern.

In another embodiment, the invention provides a semiconductor device, comprising; a gate structure on a semiconductor substrate, wherein the gate structure comprises a stacked combination a gate dielectric pattern, a gate, a capping layer pattern and an epitaxial blocking layer pattern, sidewall spacers on the gate structure covering at least sidewall portions of the gate dielectric pattern, the gate, and the capping layer pattern, wherein the epitaxial blocking layer pattern is exposed on a top surface of the gate structure, and elevated source/drain regions epitaxially grown on the semiconductor substrate outside the gate structure.

### BRIEF DESCRIPTION OF THE DRAWINGS

Embodiments of the invention will be described with reference to the attached drawings in which:

Figure (FIG.) 1 is a flow chart summarizing a fabrication method for a semiconductor device according to an embodiment of the invention;

FIGS. 2 through 10 are sectional views sequentially illustrating a fabrication method for a semiconductor device according to an embodiment of the invention;

FIG. 11 is a flow chart summarizing a fabrication method for a semiconductor device according to another embodiment of the invention;

FIGS. 12 through 22 are sectional views sequentially illustrating a fabrication method for a semiconductor device according to another embodiment of the invention; and

FIG. 23 is a flow chart summarizing a fabrication method for a semiconductor device according to another embodiment of the invention;

### DESCRIPTION OF EMBODIMENTS

Advantages and features of the invention as well as methods for accomplishing the same will be understood by reference to the following description of embodiments with reference to the accompanying drawings. The invention may, however, be embodied in many different forms and should not be construed as being limited to only the illustrated embodiments. Rather, these embodiments are presented as teaching examples. Throughout the drawings and written description, like reference numerals will be used to refer to like or similar elements.

The term “and/or” when used, includes any and all combinations of one or more of the associated or listed items. Unless specifically stated, a word in singular form also represents plural form. The terms “comprise” and “comprising” used in the specification may include elements, steps, operations and/or devices specifically mentioned in the specification, as well as other elements, steps, and operations, and/or devices.

Hereinafter, a fabrication method for a semiconductor device according to an embodiment of the invention will be described with reference to FIGS. 1 through 10.

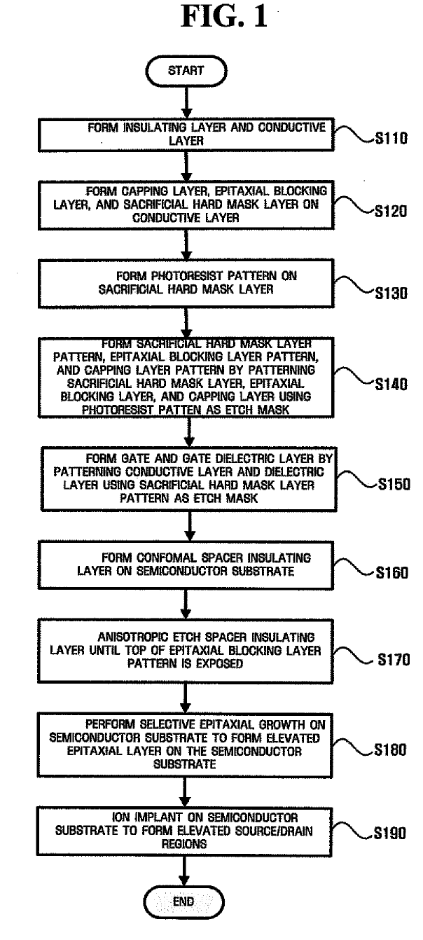

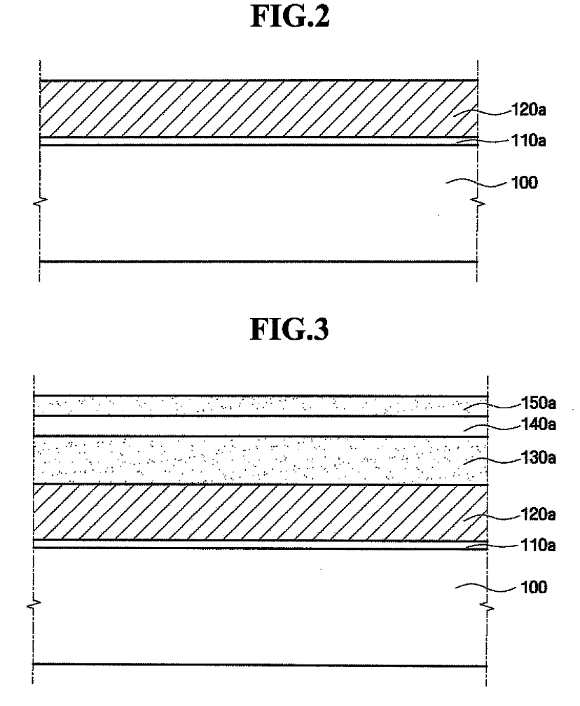

FIG. 1 is a flow chart summarizing a fabrication method for a semiconductor device according to an embodiment of the invention. FIGS. 2 through 10 are sectional views sequentially and further illustrating the fabrication method of FIG. 1.

Referring to FIGS. 1 and 2, a dielectric layer 110a and a conductive layer 120a are formed on a semiconductor substrate 100 (S110). Prior to these depositions, the semiconductor substrate 100 has preferably been divided into an active region and a non-active region by an isolation layer such as shallow trench isolation (STI) and field oxide (FOX). Thereafter, the dielectric layer 110a and the conductive layer 120a may be sequentially formed on the semiconductor substrate 100.

The semiconductor substrate 100 may be a silicon on insulator (SOI) substrate, GaAs substrate, SiGe substrate, ceramic substrate, quartz substrate, or glass substrate such as those used in the implementation of a display device. In one exemplary embodiment, a P-type semiconductor substrate is used as the semiconductor substrate 100. This type of semiconductor substrate may be formed in one related example by means of a P-type epitaxial layer grown on the surface of the semiconductor substrate.

The dielectric layer 110a is a layer adapted to the formation of a gate dielectric layer and may be formed as a silicon oxide layer grown via a thermal oxidation process applied to the semiconductor substrate 100. Alternately, the dielectric layer 110a may be formed from SiON, GexOyNz, GexSiyOz, a high-k material, the combination thereof, or a stacked combination thereof. For example, a competent high-k material may be HfO2, ZrO2, Al2O3, Ta2O5, hafnium silicate, zirconium silicate, or a combination thereof, but the present invention is not limited to only these materials.

The conductive layer 120a may be formed as an impurity doped polysilicon layer. Alternately, the conductive layer 120a may be formed as a metal layer such as W or TiN, and a composition layer including a metal layer.

Next, referring to FIGS. 1 and 3, an epitaxial blocking layer 140a and a sacrificial hard mask layer 150a are formed on the conductive layer 120a (S120). However, a capping layer 130a may optionally be formed on the conductive layer 120a prior to these depositions. In one example, the capping layer 130a is formed from a nitride layer deposited using a conventional chemical vapor deposition (CVD) process.

Thereafter, the epitaxial blocking layer 140a may be formed on the capping layer 130a. The epitaxial blocking layer 140a is adapted to block the growth of an epitaxial layer during a subsequently performed selective epitaxial growth process. Many different materials may be used as epitaxial blocking layer 140a (i.e., a material layer having relatively small epitaxial growth characteristics as compared to semiconductor substrate 100). In one embodiment, a layer having a greater epitaxial growth selectivity than a nitride layer is used. For example, the epitaxial blocking layer 140a may be formed from an oxide layer deposited using a conventional CVD process.

Next, the sacrificial hard mask layer 150a is formed on the epitaxial blocking layer 140a. Since the sacrificial hard mask layer 150a is used for the etch mask during subsequently applied gate patterning processes, it is formed to have a sufficient width in view of same. The sacrificial hard mask layer 150a may be formed, for example, from a nitride layer.

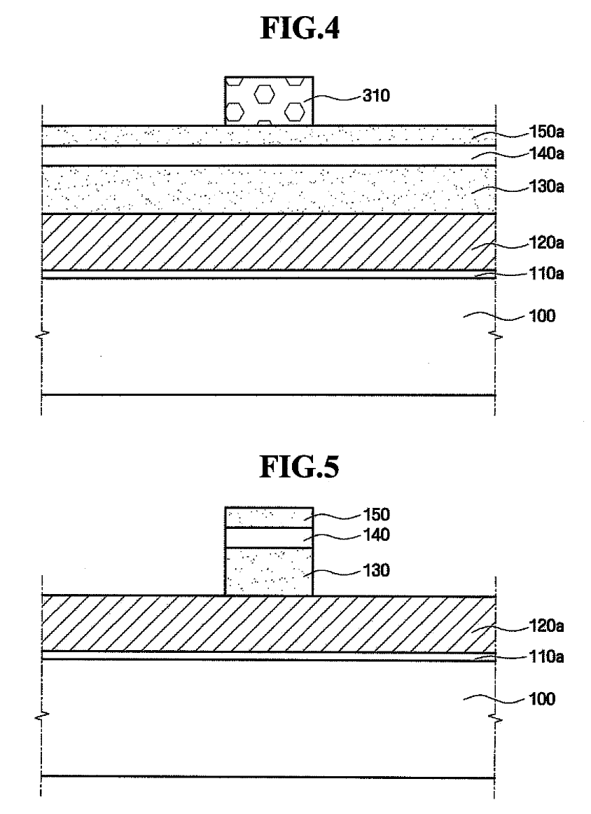

Next, referring to FIGS. 1 and 4, a photoresist pattern 310 is formed on the sacrificial hard mask layer 150a. (S130). The photoresist pattern 310 may be formed by applying a conventional photoresist coating to the sacrificial hard mask layer 150a followed by photolithography and etch processes.

Next, referring to FIGS. 1 and 5, using the photoresist pattern 310 as an etch mask, a sacrificial hard mask layer pattern 150, an epitaxial blocking layer pattern 140, and a capping layer pattern 130 are patterning (S140). The photoresist pattern 310 may be partially removed during the process of patterning the sacrificial hard mask layer 150a, epitaxial blocking layer 140a and capping layer 130a. After patterning of the underlying material layers, the remaining photoresist pattern 310 is then removed using, for example, a conventional ashing process.

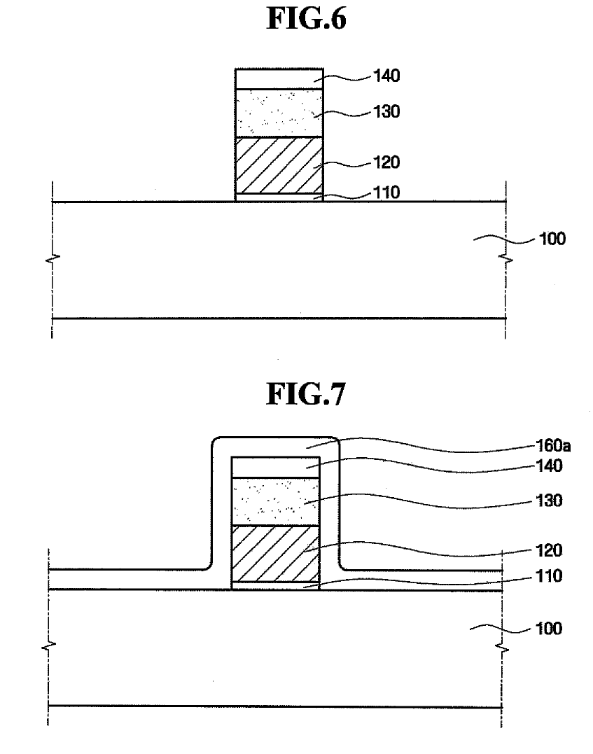

Next, referring to FIGS. 1 and 6, using the sacrificial hard mask layer pattern 150 as an etch mask, a gate 120 is patterned from the conductive layer 120a, and a gate dielectric pattern 110 formed from the dielectric layer 110a (S150). A dry etching process, such as plasma etching or reactive ion etching, may be used to pattern of conductive layer 120a and dielectric layer 110a. Here, Cl, CF4, and F may be used as an etching gas during the dry etching process. Where the conductive layer 120a and dielectric layer 110a are patterned using the sacrificial hard mask layer pattern 150 as the etch mask, the sacrificial hard mask layer pattern 150 may also be etched during the dry etching process. Thus, following the gate patterning the sacrificial hard mask layer pattern 150 may be either partially or entirely removed. FIG. 6 illustrates a case where the sacrificial hard mask layer pattern 150 is entirely removed.

Then, referring to FIGS. 1 and 7, a spacer insulating layer 160a is conformally formed over the semiconductor substrate 100, including the “gate structure” formed by at least gate 120, gate dielectric pattern 110, epitaxial blocking layer pattern 140, and capping layer pattern 130 (S160). In one embodiment, the spacer insulating layer 160a is formed from a nitride layer or an oxynitride layer.

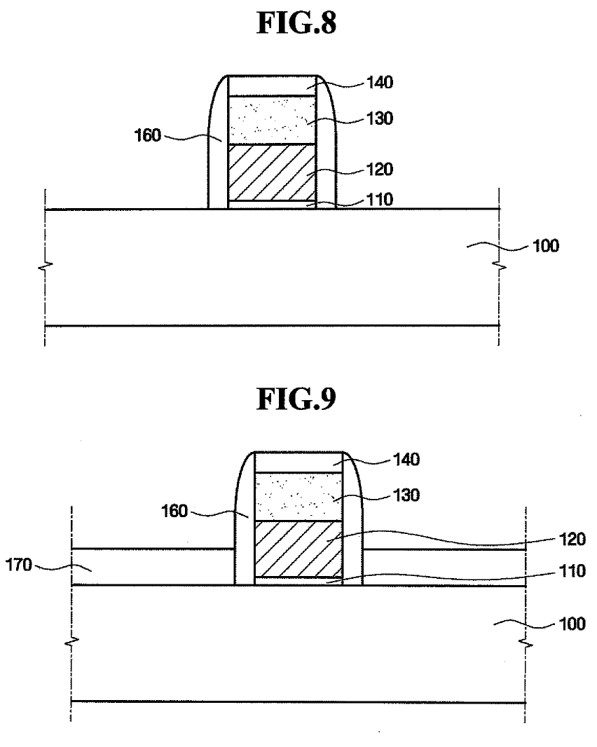

Next, referring to FIGS. 1 and 8, spacers 160 are formed by anisotropically etching the spacer insulating layer 160a of FIG. 7 until the surface of the epitaxial blocking layer pattern 140 is exposed (S170).

In other words, etching is performed to remove the spacer insulating layer 160a formed on the epitaxial block layer pattern 140. As a result, the surface of the epitaxial blocking layer pattern 140 is exposed. In a case where the sacrificial hard mask layer pattern 150 has not been entirely removed during the previous gate patterning process(es) and partially remains on the epitaxial blocking layer pattern 140, the sacrificial hard mask layer 150 remaining on the epitaxial blocking layer pattern 140 is now entirely removed to expose the surface of the epitaxial blocking layer pattern 140.

Therefore, spacers 160 are formed to cover both sides of the gate structure while leaving the epitaxial blocking layer pattern 140 exposed. In this regard, the spacers 160 may cover all, some, or none of the sidewall portions of the epitaxial blocking layer pattern 140.

Next, referring to FIGS. 1 and 9, an elevated epitaxial layer 170 is formed on the semiconductor substrate 100 using a selective epitaxial growth process (S180). The selective epitaxial growth may take the form of one or more processes, such as chemical vapor deposition (CVD), reduced pressure chemical vapor deposition (RPCVD), ultra-high vacuum chemical vapor deposition (UHVCVD), etc.

In one embodiment, the selective epitaxial growth is performed using a silicon source gas, such as SiH4, dichlorosilane (SiH2Cl2; DCS), and/or trichlorosilane (SiHCl3; TCS). Also, when performing the selective epitaxial growth, gas including Cl atoms such as HCl, Cl2 may be supplied with the silicon source gas. Providing the gas including Cl atoms during the selective epitaxial growth improves the selectivity ratio of the selective epitaxial growth process relative to the semiconductor substrate 100, as compared with an oxide layer or nitride layer.

Here, however, since the epitaxial blocking layer pattern 140 is formed on the capping layer pattern 130, the selective epitaxial growth is only performed on the exposed portions of semiconductor substrate 100 outside the gate structure. Little or no selective epitaxial growth occurs on the epitaxial blocking layer pattern 140. Thus, the selective epitaxial growth process is improved and exhibits a silicon layer growth selectivity relative to the exposed portions of the semiconductor substrate 100 even in the presence of a small amount of gas including Cl atoms.

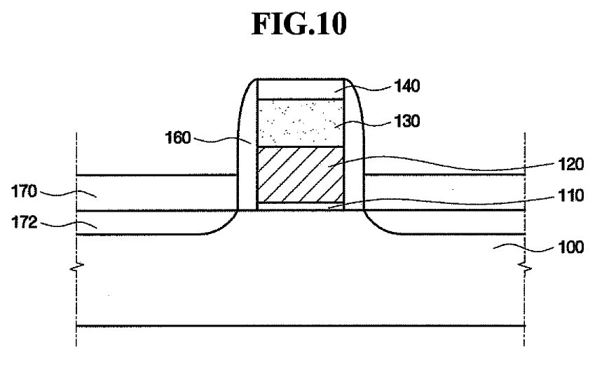

Next, referring to FIGS. 1 and 10, elevated source/drain regions 172 are then formed “on” the semiconductor substrate 100 by performing ion implantation process (S190). In this context, the term “on” describes an ion implantation process wherein source/drain regions are selectively formed in portions of elevated source drain layer 170, in the upper surface of semiconductor substrate 100, or both.

At this time and under the working assumptions above regarding the P-type nature of semiconductor substrate 100, arsenic or phosphorous may be ion implanted at a high concentration using an implantation energy in the range of tens of keV in order to form an N-type transistor. Boron may be ion implanted at a high concentration using an implantation energy in the range of tens of keV in order to form a P-type transistor.

According to the fabrication method for a semiconductor device in accordance with an embodiment of the invention, since epitaxial blocking layer pattern 140 is formed on the gate 120, the subsequently grown epitaxial layer is formed on only the exposed portions of semiconductor substrate 100. In relation to one conventional approach, the foregoing fabrication method forms the epitaxial blocking layer pattern 140 on the gate 120 instead of a dielectric layer which is highly susceptible to etching damage. Thus, even in the presence of a gas containing Cl atoms, the selectivity of the applied epitaxial growth process is not impaired, and epitaxial layer 170 may be more reliably formed.

The resulting semiconductor device according to an embodiment of the invention is described with reference to FIG. 10.

Referring to FIG. 10, a gate dielectric pattern 110, a gate 120, a capping layer pattern 130, an epitaxial blocking layer pattern 140, spacers 160, and source/drain regions 172 are formed on a semiconductor substrate 100.

A gate structure is formed by sequentially stacking the gate dielectric pattern 110, the gate 120, the capping layer pattern 130, and the epitaxial blocking layer pattern 140. The spacers 160 are formed on both sides of the gate structure, but the sidewall portions of the epitaxial blocking layer pattern 140 may or may not be fully covered by the spacers 160. A top surface of the epitaxial blocking layer pattern 140 is exposed.

Here, the capping layer pattern 130 may be formed from a nitride layer and the epitaxial blocking layer pattern 140 may be formed from an oxide layer. The source/drain regions 172 may be formed from the elevated epitaxial layer 170 and/or the semiconductor substrate 100.

According to the foregoing semiconductor device, since the epitaxial blocking layer 140 is formed on the top of the gate structure, the reliability with which the epitaxial layer 170 is selectively grown on the semiconductor substrate 100 may be improved.

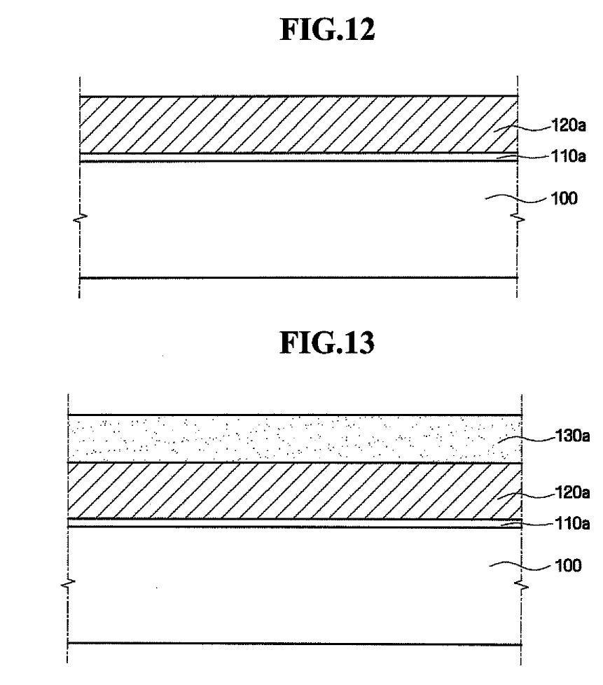

Hereinafter, referring to FIGS. 11 through 22, a fabrication method for a semiconductor device according to another embodiment of the invention is described. FIG. 11 is a flow chart summarizing the fabrication method. FIGS. 12 through 22 are sectional views further illustrating the fabrication method of FIG. 11.

Throughout this description, like reference numerals will be used for like or similar elements relative to the previously described embodiments.

Referring to FIGS. 11 and 12, the dielectric layer 110a and conductive layer 120a are again formed on the semiconductor substrate 100 (S110).

As before, the semiconductor substrate 100 may be divided into an active region and a non active region by an isolation layer, such as shallow trench isolation (STI) and field oxide (FOX) prior to the sequential formation of the dielectric layer 110a and conductive layer 120a on the semiconductor substrate 100.

The dielectric layer 110a will serve as a gate dielectric layer, and may be formed from a silicon oxide layer formed by thermal oxidation of the semiconductor substrate 100. Alternately a SiON, GexOyNz, GexSiyOz, high-k material, a combination thereof, or a stacked combination thereof may be used. Here, the high-k material can be HfO2, ZrO2, Al2O3, Ta2O5, hafnium silicate, zirconium silicate, or combination thereof.

The conductive layer 120a may be formed from an impurity doped polysilicon layer, and/or a metal layer.

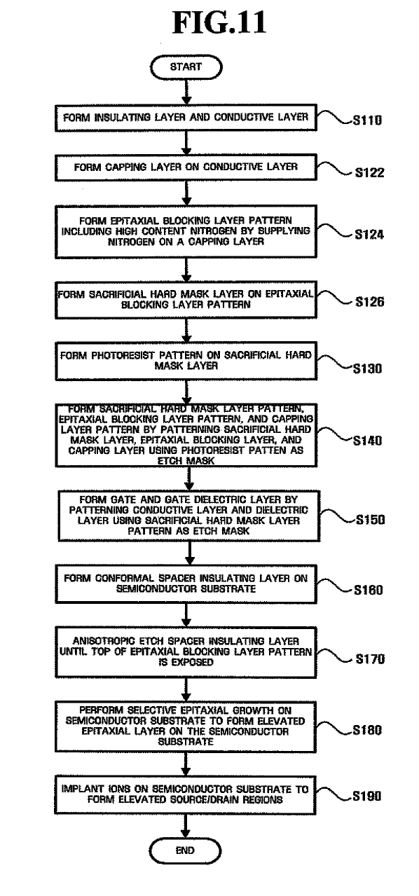

Next, referring to FIGS. 11 and 13, a capping layer 130a is formed on the conductive layer 120a (S122). The capping layer 130a may be formed using a conventional chemical vapor deposition (CVD) process. In one embodiment, the capping layer 130a is formed from a nitride layer.

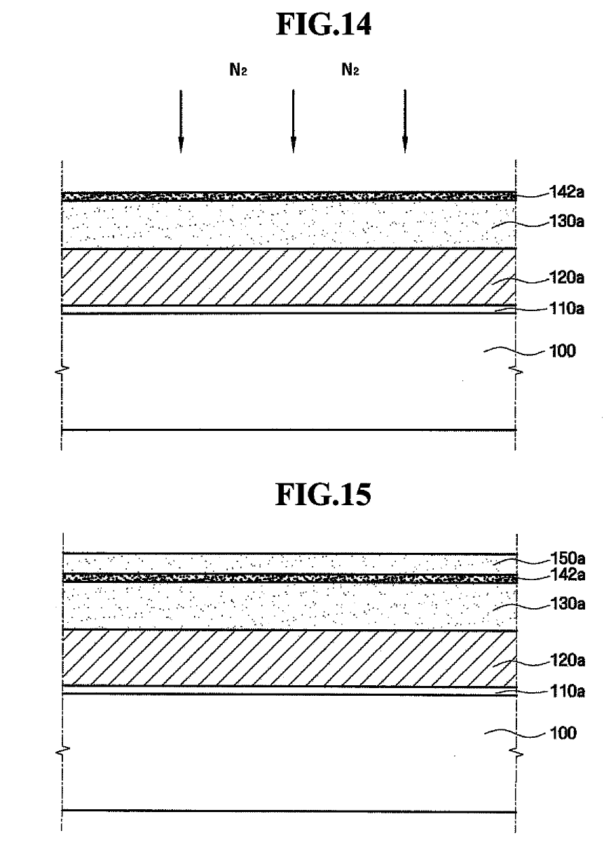

Then, referring to FIGS. 11 and 14, an epitaxial blocking layer pattern 142a including high nitrogen content is formed by supplying abundant nitrogen to the capping layer 130a (S124).

In one embodiment, nitrogen gas or a gas including nitrogen is supplied to the capping layer 130a. Alternately, a nitrogen plasma or a plasma of gas including nitrogen can be formed by supplying power. Thus, the nitrogen content of an upper portion of the nitride capping layer 130a is increased, and a nitrogen enhanced epitaxial blocking layer pattern 142a including an elevated nitrogen content is formed on the capping layer 130a.

The nitrogen enhanced epitaxial blocking layer pattern 142a formed on the capping layer 130a has a higher selectivity relative to the semiconductor substrate 100 than a normal (non-enhanced) nitride layer. In other words, if the nitrogen content of the nitride layer is increased, the nitride layer may be used as the epitaxial blocking layer 142a during the selective epitaxial growth process.

Referring to FIGS. 11 and 15, a sacrificial hard mask layer 150a is formed on the epitaxial blocking layer 142a (S126). Since the sacrificial hard mask layer 150a is used for the etch mask, which patterns the gate structure during successive processes, it is formed with a desired gate width. The sacrificial hard mask layer 150a, for example, may be formed from a nitride layer. At this time, the nitrogen content of the sacrificial hard mask layer 150a formed with a nitride layer is smaller than the nitrogen content of nitrogen enhanced epitaxial blocking layer pattern 142a formed under the sacrificial hard mask layer 150a.

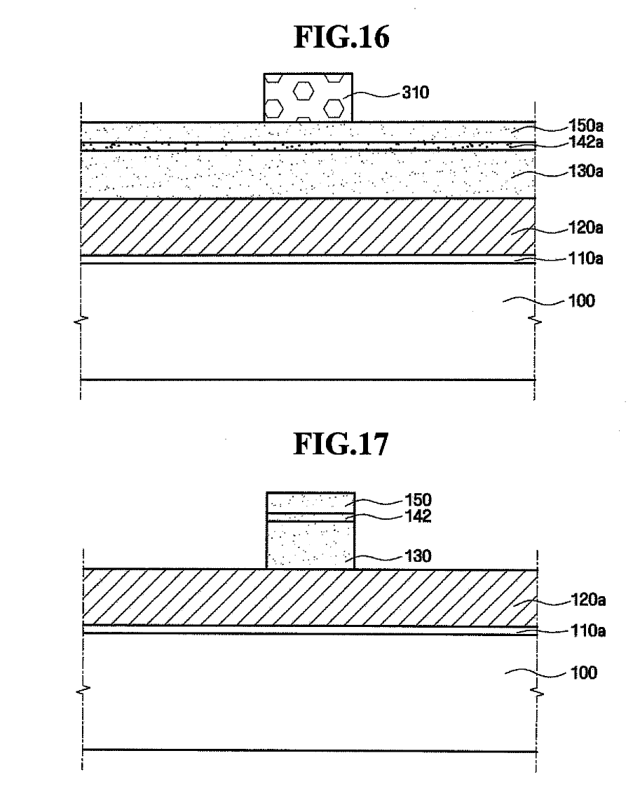

Next, referring to FIGS. 11 and 16, a photoresist pattern 310 is formed on the sacrificial hard mask layer 150a (S130). The photoresist pattern 310 may be formed from a conventional photoresist coating on the sacrificial hard mask layer 150a, followed by photolithography and etching processes.

Next, referring to FIGS. 11 and 17, using the photoresist pattern 310 as an etch mask, the sacrificial hard mask layer pattern 150, the epitaxial blocking layer pattern 142, and the capping layer pattern 130 are patterning to form part of the gate structure (S140). The photoresist pattern 310 is then removed by performing an ashing process.

Next, referring to FIGS. 11 and 18, using the sacrificial hard mask layer pattern 150 as an etch mask, a gate 120 and a gate dielectric pattern 110 are patterning to complete the gate structure (S150).

If the conductive layer 120a and the dielectric layer 110a are patterned using the sacrificial hard mask layer pattern 150 as the etch mask, the sacrificial hard mask layer pattern 150 can be also etched and removed. Here, the sacrificial hard mask layer pattern 150 can be either partially or entirely removed. FIG. 18 illustrates the case where the sacrificial hard mask layer pattern 150 is entirely removed.

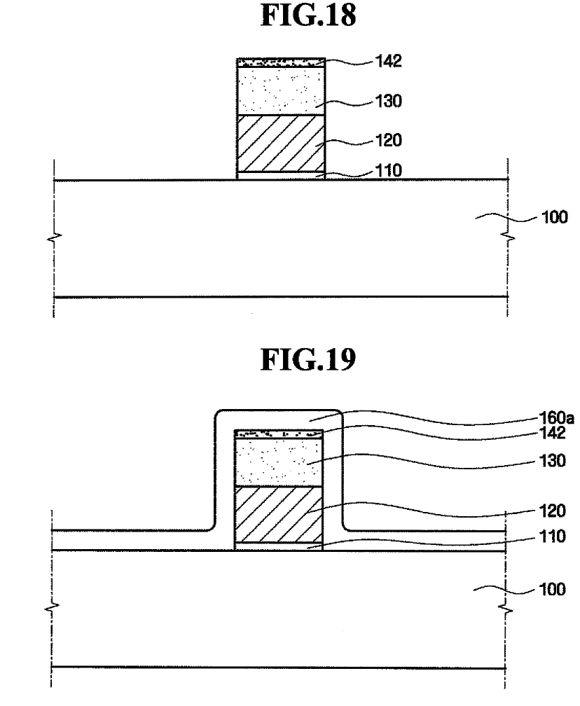

Then, referring to FIGS. 11 and 19, a spacer insulating layer 160a is conformally formed on the semiconductor substrate 100 including the gate structure (S160). The spacer insulating layer 160a may be formed from a nitride layer or an oxynitride layer.

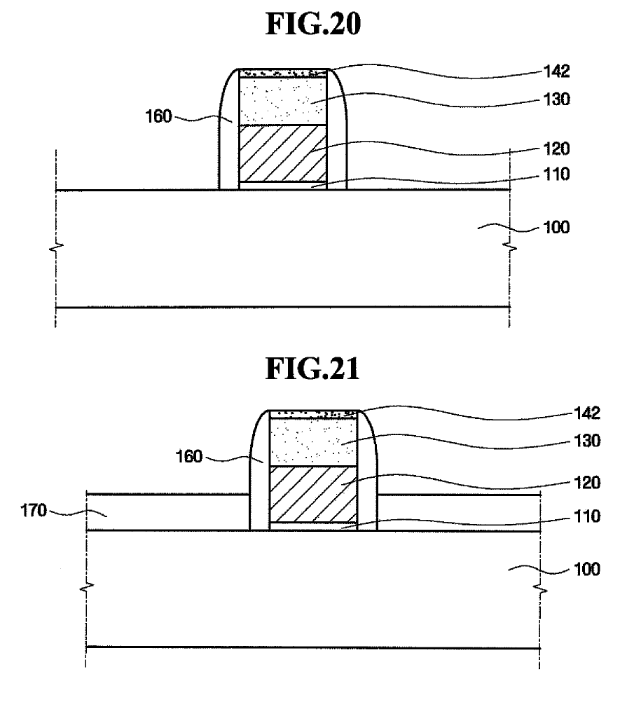

Next, referring to FIGS. 11 and 20, spacers 160 are formed by anisotropic etching of the spacer insulating layer 160a of FIG. 19 until the surface of the epitaxial blocking layer pattern 142 is exposed (S170).

In other words, etching is performed to remove all the spacer insulating layer 160a formed on the epitaxial block layer pattern 142. As a result, the surface of the epitaxial blocking layer pattern 140 is exposed. In a case where the sacrificial hard mask layer pattern 150 is not entirely removed during the previous gate patterning process and partially remains on the epitaxial blocking layer pattern 142, the sacrificial hard mask layer 150 on the epitaxial blocking layer pattern 142 is entirely removed to expose the surface of the epitaxial blocking layer pattern 142.

Next, referring to FIGS. 11 and 21, an elevated epitaxial layer 170 is formed on the semiconductor substrate 100 by performing selective epitaxial growth on the semiconductor substrate 100 (S180).

The selective epitaxial growth can be performed using processes including chemical vapor deposition (CVD), reduced pressure chemical vapor deposition (RPCVD), ultra-high vacuum chemical vapor deposition (UHVCVD), but is not limited to such processes.

In one embodiment, the selective epitaxial growth is performed by providing a silicon source gas, such as SiH4, dichlorosilane (SiH2Cl2; DCS), and trichlorosilane (SiHCl3; TCS). Also, when performing the selective epitaxial growth, a gas including Cl atoms such as HCl or Cl2 may be supplied in addition to the silicon source gas. Providing the gas including Cl atoms during the selective epitaxial growth improves the selectivity ratio of the selective epitaxial growth on silicon.

Here, since the epitaxial blocking layer pattern 142 is formed on the capping layer pattern 130, the selective epitaxial growth is only performed on the exposed semiconductor substrate 100, and no selective epitaxial growth is performed on the epitaxial blocking layer pattern 142.

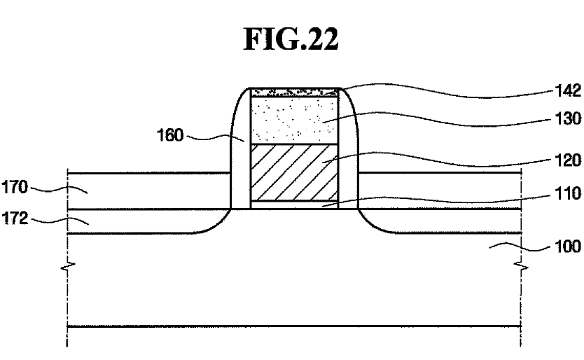

Next, referring to FIGS. 11 and 22, elevated source/drain regions 172 are formed on the semiconductor substrate 100 by performing ion implantation process (S190).

According to the foregoing fabrication method, since the epitaxial blocking layer pattern 142 is formed on the gate 120, the epitaxial layer is not formed on the gate structure but only on exposed portions of the semiconductor substrate 100 during the selective epitaxial growth process. That is, in the presence of a gas including Cl atoms, the selectivity of the selective epitaxial growth process on the semiconductor substrate 100 is increased, so that epitaxial layer 170 may be reliably formed. Also, since nitrogen is supplied after formation of the capping layer 130a, and the epitaxial blocking layer pattern 142 is formed, the process can be simplified and the productivity can be increased.

A semiconductor device consistent with the foregoing method embodiment is illustrated in FIG. 22. Referring to FIG. 22, a gate structure is formed by sequentially stacking a gate dielectric pattern 110, a gate 120, a capping layer pattern 130, and a nitrogen enhanced epitaxial blocking layer pattern 142. Spacers 160 are formed on sidewall portions of the gate structure. However, the sidewall portions of the nitrogen enhanced epitaxial blocking layer pattern 142 may or may not be fully covered.

Here, the capping layer pattern 130 may be formed from a nitride layer and the nitrogen enhanced epitaxial blocking layer pattern 142 may be formed from a nitride layer having its nitrogen content elevated above that of the capping layer 130a.

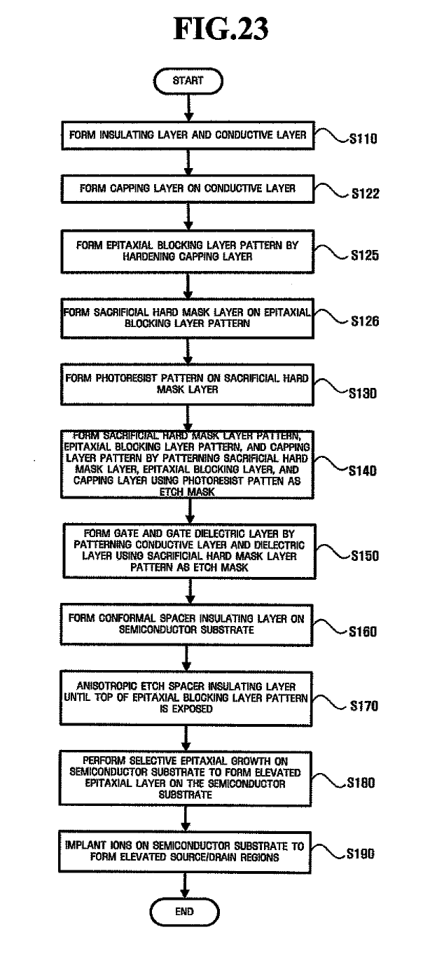

Hereinafter, a fabrication method for a semiconductor device according to another embodiment of the invention will be described with reference to FIGS. 12 through 23. FIG. 23 is a flow chart summarizing this method.

The only material difference between this exemplary embodiment and the one previously described in relation to FIG. 11 is the nature and formation of the epitaxial blocking layer 142. In this following embodiment, this layer is formed by hardening a top surface portion of the capping layer 130 (S125).

In one embodiment, the capping layer 130 may be hardened by applying a heat treatment to the semiconductor substrate 100 to form hardened epitaxial blocking layer pattern 142. That is, the hardened epitaxial blocking layer pattern 142 is formed directly from the capping layer 130a. Because the hardened epitaxial blocking layer pattern 142 is harder than the capping layer 130 it exhibits a greater selectivity relative to the semiconductor substrate 100 than the nitride capping layer 130. In other words, as the nitrogen content of the nitride capping layer 130 is increased, the nitride layer may be effectively used as the epitaxial blocking layer pattern 142 during the subsequently applied selective epitaxial growth process.

As described above, in a semiconductor device fabricated according to a method embodiment of the invention, one or more than one of the following effects may be observed. First, since an epitaxial blocking layer pattern is formed on a gate structure, the selectivity during a subsequently performed selective epitaxial growth process is increased. Second, since selectivity of a selective epitaxial growth on a semiconductor substrate is increased, an epitaxial layer and the semiconductor device may be formed with greater reliability.

While the present invention has been particularly shown and described with reference to exemplary embodiments thereof, it will be apparent to those skilled in the art that the scope of the invention is given by the appended claims. Therefore, it should be understood that the above embodiments are not limitative, but illustrative in all aspects.

What is claimed is:

1. A method of fabricating a semiconductor device, comprising:
sequentially forming a dielectric layer, a conductive layer, a capping layer, an epitaxial blocking layer, and a sacrificial hard mask layer on a semiconductor substrate;
forming a photoresist pattern on the sacrificial hard mask layer;
using the photoresist pattern as a mask, patterning the sacrificial hard mask layer to form a sacrificial hard mask pattern, patterning the epitaxial blocking layer to form an epitaxial blocking layer pattern, and patterning the capping layer to form a capping layer pattern;
patterning the conductive layer to form a gate and patterning the dielectric layer to form a gate dielectric pattern, wherein the epitaxial blocking layer pattern, capping layer pattern, the gate, and gate oxide pattern form a gate structure;
conformally forming a spacer insulating layer on the semiconductor substrate including the gate structure;
forming spacers by anisotropically etching the spacer insulating layer to expose the epitaxial blocking layer pattern;
forming an elevated epitaxial layer on the semiconductor substrate outside the gate structure using a selective epitaxial growth process; and
forming elevated source/drain regions by applying an ion implantation process to the semiconductor substrate following formation of the elevated epitaxial layer.

2. The method of claim 1, wherein the epitaxial blocking layer is an oxide layer.

3. The method of claim 1, wherein the capping layer is a nitride layer.

4. The method of claim 3, wherein the nitrogen content of the epitaxial blocking layer is greater than the nitrogen content of the capping layer.

5. The method of claim 3, wherein the epitaxial blocking layer is a nitride layer having a higher atomic density than the capping layer.

6. The method of claim 1, wherein the sacrificial hard mask layer is a nitride layer.

7. The method of claim 1, wherein the sacrificial hard mask layer pattern is partially removed during the patterning of the conductive layer and the patterning of the dielectric layer, and the method further comprises:
prior to conformally forming the spacer insulating layer, removing a remaining portion of the sacrificial hard mask pattern.

8. The method of claim 1, wherein the sacrificial hard mask layer pattern is entirely removed during the patterning of the conductive layer and the patterning of the dielectric layer to expose the epitaxial blocking layer pattern.

9. The method of claim 8, wherein at least a portion of the sidewalls of the epitaxial blocking layer pattern are exposed by the spacers.

10. A method of fabricating a semiconductor device, comprising:
forming a gate structure on a semiconductor substrate, the gate structure comprising a stacked combination a gate dielectric pattern, a gate, a capping layer pattern and an epitaxial blocking layer pattern;
forming sidewall spacers on the gate structure covering at least sidewall portions of the gate dielectric pattern, the gate, and the capping layer pattern, wherein the epitaxial blocking layer pattern is exposed on a top surface of the gate structure;
forming an elevated epitaxial layer on the semiconductor substrate outside the gate structure using a selective epitaxial growth process; and
forming elevated source/drain regions by applying an ion implantation process to the semiconductor substrate following formation of the elevated epitaxial layer;
wherein the epitaxial blocking layer is a nitrogen enhanced layer relative to the capping layer pattern.

11. The method of claim 10, wherein the nitrogen enhanced epitaxial blocking layer is formed by supplying abundant nitrogen to an upper surface of the capping layer, such that the nitrogen content of the epitaxial blocking layer is greater than the capping layer pattern.

12. The method of claim 10, wherein the nitrogen enhanced epitaxial blocking layer is formed by hardening an upper surface of the capping layer, such that the epitaxial blocking layer has a higher atomic density than the capping layer.

13. A semiconductor device, comprising:
a gate structure on a semiconductor substrate, wherein the gate structure comprises a stacked combination a gate dielectric pattern, a gate, a capping layer pattern and an epitaxial blocking layer pattern;
sidewall spacers on the gate structure covering at least sidewall portions of the gate dielectric pattern, the gate, and the capping layer pattern, wherein the epitaxial blocking layer pattern is exposed on a top surface of the gate structure; and
elevated source/drain regions epitaxially grown on the semiconductor substrate outside the gate structure.

14. The semiconductor device of claim 13, wherein the epitaxial blocking layer pattern is an oxide layer.

15. The semiconductor device of claim 13, wherein the capping layer pattern is a nitride layer.

16. The semiconductor device of claim 15, wherein the epitaxial blocking layer pattern is the nitride layer having a higher atomic density than the capping layer.

17. The semiconductor device of claim 15, wherein the epitaxial blocking layer pattern is a nitride layer having a greater nitrogen content than that of the capping layer pattern.

18. The semiconductor substrate of claim 13, wherein the spacers cover sidewall portions of the epitaxial blocking layer pattern.

19. The semiconductor substrate of claim 13, wherein the spacers partially cover sidewall portions of the epitaxial blocking layer pattern.
